(19) United States
(12) Patent Application Publication
(10) Pub. No.: US 2025/0307483 A1
(43) Pub. Date: Oct. 2, 2025

(54) Ingesting Technical Data Packages for Digital Engineering Ecosystems

(71) Applicant: Science Applications International Corporation, Reston, VA (US)

(72) Inventors: Christopher G. Finlay, Saunderstown, RI (US); Jacob Donovan, Carmel, IN (US); Tyler C. Richardett, Chicago, IL (US); Matthew Peterson, Meggett, SC (US)

(21) Appl. No.: 19/090,508

(22) Filed: Mar. 26, 2025

Related U.S. Application Data
(60) Provisional application No. 63/569,760, filed on Mar. 26, 2024.

(51) Int. Cl. G06F 30/12; G06F 30/27

(52) U.S. Cl. CPC G06F 30/12; G06F 30/27

(57) ABSTRACT

The present disclosure describes analyzing a plurality of files to generate a file containing pertinent information from each of the plurality of files. The plurality of files may be part of a technical data package. The present disclosure describes one or more machine learning algorithms configured to extract parts, components, elements, features, instructions, and the like from text, tables, images, and metadata contained in each of the plurality of files. The parts, components, elements, features, instructions, and the like may be aggregated into a single file, which may be used to generate a bill of materials and other items with a product lifecycle management (PLM).

### CROSS-REFERENCE TO RELATED APPLICATIONS

This application claims the benefit of U.S. Provisional Application No. 63/569,760, filed Mar. 26, 2024, the entirety of which is hereby incorporated by reference for all purposes.

### BACKGROUND OF THE INVENTION

A technical data package (TDP) is a set of electronic files, created by a product development organization, that describes a product or item. These files may include 3D models, CAD drawings, product manufacturing information (PMI), bills of material (BOMs), requirements documents, and any other necessary data. Because of the number of files and the variety of files included therein, TDPs are difficult to ingest into product lifecycle management (PLM) tools. Computer systems may not be able to read, or understand, 3D models and/or CAD drawings and the relationships between the items. Moreover, computer systems may have difficulty reading and/or understanding PMI and BOMs. Accordingly, deciphering the contents of a TDP becomes time-consuming and difficult. Moreover, there is no clear format for the data to be entered into a PLM tool. This leads to computers being unable to process TDPs and/or requiring hours of an engineer's time to interpret the TDP data.

### SUMMARY OF THE INVENTION

The following presents a simplified summary of various aspects described herein. This summary is not an extensive overview, and is not intended to identify key or critical elements or to delineate the scope of the claims. The following summary merely presents some concepts in a simplified form as an introductory prelude to the more detailed description provided below.

Aspects of the disclosure generally relate to processing information contained in a plurality of files and, more specifically, to training one or more machine learning models to process information contained in a plurality of files to generate a file containing pertinent information from each of the plurality of files. In particular, the present disclosure relates to training one or more machine learning models to process information contained in a plurality of files associated with a technical data package of an engineering project. Based on the analysis of the one or more machine learning models, the one or more machine learning models may be configured to generate a file containing pertinent information from each of the plurality of files. The file may then be inputted into a product lifecycle management (PLM) tool to assist and/or manage supply chains, production, change orders, quality workflows, and the like. Once the one or more machine learning models are trained, the one or more machine learning models may be deployed as part of a digital engineering ecosystem.

The PLM tool, with the one or more trained machine learning models, may receive one or more data packages. Upon receiving the one or more data packages, the PLM tool may create a first data package item. Once the first data package item is created, a first TDP associated with the first data package item may be received. The first TDP may be analyzed using the one or more trained machine learning models. The one or more trained machine learning models may work through the first TDP asynchronously in order to allow users to continue working in other areas of the PLM tool. While processing the first TDP, the computing device may begin by decompressing (e.g., unzipping) the first TDP. After decompressing the first TDP, the computing device (e.g., one or more machine learning models executing on the computing device) may organize the data, information, and/or files contained therein. The one or more machine learning models may then iterate through each file to identify parts, components, elements, features, instructions, and the like. As part of the iteration, a confidence score may be generated and associated with each of the identified parts, components, elements, features, instructions, and the like. The confidence score may comprise a value indicating the probability or likelihood that the identified part, component, element, feature, and/or instruction is accurate and/or correct. Once the analysis is completed, the parts, components, elements, features, instructions, and the like may be exported to a file, which may be associated with the first data package item. In some instances, the analysis may identify any gaps or missing parts, components, elements, features, and/or instructions. An owner of the first data package item may be notified, for example, by receiving a notification that the analysis has been completed. The owner may review (e.g., interrogate) the results of the analysis performed by the one or more machine learning models. Once the owner has completed their review, the contents of the file may be uploaded (e.g., imported) into a database. By using the one or more machine learning models described herein, the functionality of the PLM tool may be improved by reducing the amount of time that a computing device needs to process and/or analyze a plurality of files to identify parts, components, elements, features, instructions, etc. and store the parts, components, elements, features, instructions, etc. in a single file that can be used to order materials and/or to construct parts, components, elements, features, instructions, etc.

These and other features are discussed in greater detail below.

### BRIEF DESCRIPTION OF DRAWINGS

The present disclosure is illustrated by way of example and not limited in the accompanying figures in which like reference numerals indicate similar elements and in which:

FIG. 1 shows an example of a digital engineering ecosystem, including interactions between software and relationships of software to engineering project phases, in accordance with one or more aspects of the disclosure;

FIG. 2 shows an example network in which a digital engineering ecosystem may be implemented;

FIG. 3 shows an example of digital engineering ecosystem software hosted on a computing device in accordance with one or more aspects of the disclosure;

FIGS. 4A and 4B show an example process for ingesting a plurality of files associated with a technical data package in accordance with one or more aspects of the disclosure;

FIG. 5 shows an example of ingesting a plurality of files using the product lifecycle management tool and the one or more machine learning models in accordance with one or more aspects of the disclosure; and

FIG. 6 shows an example of a computing device in accordance with one or more aspects of the disclosure.

### DETAILED DESCRIPTION OF THE INVENTION

In the following description of the various embodiments, reference is made to the accompanying drawings, which form a part hereof, and in which is shown by way of illustration various embodiments in which aspects of the disclosure may be practiced. It is to be understood that other embodiments may be utilized and structural and functional modifications may be made without departing from the scope of the present disclosure. Aspects of the disclosure are capable of other embodiments and of being practiced or being carried out in various ways. Also, it is to be understood that the phraseology and terminology used herein are for the purpose of description and should not be regarded as limiting. Rather, the phrases and terms used herein are to be given their broadest interpretation and meaning. The use of “including” and “comprising” and variations thereof is meant to encompass the items listed thereafter and equivalents thereof as well as additional items and equivalents thereof.

As noted above, technical data packages (TDPs) are difficult to ingest into product lifecycle management (PLM) tools. Computer-based tools for reading and/or understanding the contents of a TDP are a time-consuming and difficult endeavor because the computer-based tools have difficulties deciphering the contents of a TDP, determining how the data should be formatted for input into a PLM tool, and, ultimately, formatting the data for input into the PLM tool. Creating the data (e.g., a bill of materials (BOM)) from the TDP for input into a PLM tool is essential for this process, however it requires hours of time interpreting the TDP data if a BOM is not included in the TDP.

By way of introduction, aspects described herein may relate to training one or more machine learning models to process (e.g., parse) information contained in a plurality of files to generate a file containing pertinent information from each of the plurality of files; the file may then be inputted into a PLM tool that manages all of the information and processes at every step of a product or service lifecycle across globalized supply chains. This information includes the data from items, parts, products, documents, requirements, engineering change orders, and/or quality workflows. To train the one or more machine learning models, a corpus of data may be provided to the one or more machine learning models. The corpus of data may be divided into training data and testing data. Preferably, 65% to 85% of the corpus of data would form the training data, while the remaining 15% to 35% of the corpus of data would be test data. Preferably, the corpus of data may comprise TDPs that include bills of material. The one or more machine learning models may be trained using the training data, while the testing data would be used to help the machine learning model(s) achieve convergence (i.e., an error range with an acceptable tolerance). Once the one or more machine learning models were trained and/or achieved convergence, the one or more machine learning models may be deployed as part of a digital engineering ecosystem to ingest TDPs.

A PLM tool, with the one or more trained machine learning models, may receive one or more data packages. Upon receiving the one or more data packages, the PLM tool may create a first data package item. As part of creating the first data package item, certain information may be stored (e.g., saved), including, for example, a name of the first data package item, a description of the first data package item, an owner of the first data package item, and/or a date/time the first data package item was received with the one or more data packages. After the first data package item is created, a first TDP may be added to the first data package item. The first TDP may be analyzed using the one or more trained machine learning models. The one or more trained machine learning models may work through the first TDP asynchronously in order to allow users to continue working in other areas of the PLM tool. That is, the one or more machine learning models do not restrict the PLM tool's operations while the one or more machine learning models process (e.g., investigate) the first TDP.

In operation, the one or more machine learning models may receive the first TDP. Typically, the first TDP may be a compressed (e.g., zipped) file. A computing device may decompress (e.g., unzip) the first TDP. After decompressing the first TDP, the computing device (e.g., one or more machine learning models executing on the computing device) may identify each type of file contained in the first TDP and organize the data, information, and/or files contained therein. The one or more machine learning models may then iterate through each file to extract text, tables, drawings, metadata, etc. After extracting text, tables, drawings, metadata, etc., the information may be analyzed to identify parts, components, elements, features, instructions, and the like. The analysis may remove duplicate, or repeated, parts, components, elements, features, instructions, etc., for example, based on or in response to receiving authorization to remove (e.g., delete) duplicate, or repeated, parts, components, elements, features, instructions, etc. In some instances, the analysis may include aggregating a total number of each part, component, element, feature, etc. According to further examples, the analysis may identify any gaps or missing parts, components, elements, features, and/or instructions. Once the analysis is completed, the parts, components, elements, features, instructions, and the like may be exported to a file, which may be associated with the first data package item. After being associated with the first data package item, the contents of the file may be stored. An owner of the first data package item may be notified, for example, by receiving a notification that the analysis has been completed. In some instances, the PLM tool may send a first electronic communication (e.g., email, text message, push notification, etc.) to a device and/or an account (e.g., email account) associated with the owner of the first data package item. The first electronic communication may request that the owner review the file associated with the data package item. The owner may review (e.g., interrogate) the results of the analysis performed by the one or more machine learning models. The review may allow the owner to edit the file. Once the owner has completed their review, the PLM tool may receive a second electronic communication indicating approval of the file. Upon receiving approval, the contents of the file may be uploaded (e.g., imported) into a database. The upload (e.g., import) may save each of the parts, components, elements, features, instructions, etc. identified in the analysis to the database. In some instances, the database may identify relationships between the parts, components, elements, features, instructions, etc. By using the one or more machine learning models described herein, the functionality of the PLM tool may be improved by reducing the amount of time that a computing device needs to process and/or analyze a plurality of files to identify parts, components, elements, features, instructions, etc. and store the parts, components, elements, features, instructions, etc. in a single file that can be used to order materials and/or to construct parts, components, elements, features, instructions, etc.

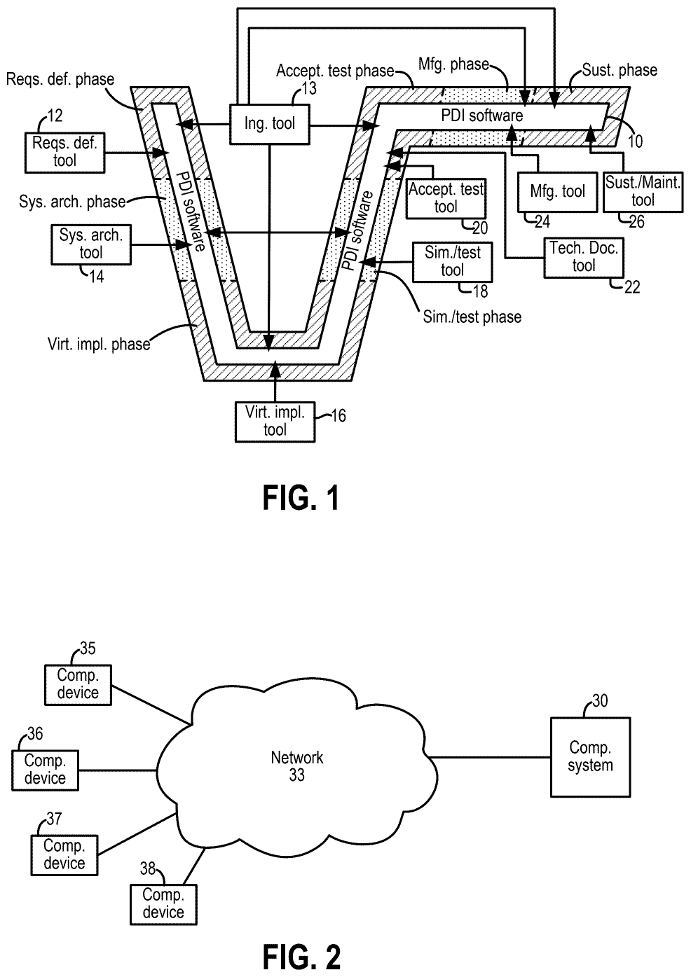

FIG. 1 shows an example of interactions of software and relationships of such software to engineering project phases in a digital engineering (DE) ecosystem. A DE ecosystem may be provided as a unified service to an enterprise, such as a corporation or other group that is performing an engineering design project. The DE ecosystem may comprise a product lifecycle management (PLM) tool, project data integration (PDI) software, and/or a plurality of engineering software tools. The DE ecosystem may be hosted on-premise, in the cloud, or provided as a hybrid solution. The DE ecosystem may further comprise a plurality of connectors, with each of the connectors corresponding to a different one of the engineering software tools and configured for generation of input data for the PLM tool based on output data from its corresponding software tool. Based on such input data, the PLM tool may generate project data, such as bills of material, that corresponds to at least a portion of the output data from the software tool, and that may be mapped or otherwise linked to other project data corresponding to output data from other software tools. Users associated with an enterprise may access the DE ecosystem via web browsers on conventional computing devices. At each stage of an engineering project, users may be able to access project data, created by the PLM tool and/or the PDI software, that may map and/or otherwise link data elements generated by the software tools. This may allow users working in later project phases to make design decisions based on reliable data from earlier phases. Moreover, providing the DE ecosystem to the enterprise as a service (e.g., software-as-a-server (SaaS)) facilitates simpler licensing of software.

As shown in FIG. 1, project phases are shown on a V diagram similar to other system engineering V diagrams. Overlaid on the V is PDI software 10. The PDI software 10 may comprise a single application, or may comprise a combination of applications (e.g., a commercially available application suite or other combination of interrelated applications). The PDI software 10, which may comprise the PLM tool and/or digital thread (DT) software, may integrate design data that is generated during each of the phases and make that integrated data available to determine links between design data elements corresponding to each of the phases. An example of software that may be used for the PDI software is the Aras Innovator® software provided by Aras Corporation of Andover, MA, US.

Ingestion tool (Ing. tool) 13 may comprise a software tool that may interface (via a connector, not shown) with the PDI software 10. The software of the requirements ingestion tool 13 may comprise a single application, or may comprise a combination of applications (e.g., a commercially available application suite or other combination of interrelated applications). The ingestion tool 13 may be configured to receive one or more files for the engineering project. In some instances, the ingestion tool 13 may comprise one or more machine learning models trained to process (e.g., parse) information contained in a technical data package to generate a bill of materials that includes parts, components, elements, features, instructions, and other required information for the engineering project. Ingestion tool 13 may output parts lists and/or instructions. As will be discussed in greater detail below, ingestion tool 13 may condense the part, components, elements, features, instructions, and other required information for the engineering project into a single file, which may be used to generate a bill of materials and/or instructions for constructing and/or building the engineering project. The ingestion tool 13 may be software that is not an extension of, and is not native to, the PDI software 10, and/or that is not provided by the provider of the PDI software 10. As shown in FIG. 1, ingestion tool 13 may be implemented, invoked, or used at any phase of the development process. That is, ingestion tool 13 may be invoked at the requirements definition phase, the system architecture phase, the virtual implementation phase, the simulation/test phase, the acceptance/testing phase, the manufacturing phase, and/or the sustainment/maintenance phase. By allowing the ingestion tool 13 to be invoked at any stage of the development process, a bill of materials and/or instructions for constructing and/or building the engineering project may be generated using the automated functionality provided by ingestion tool 13.

Requirements definition (reqs. def.) tool 12 may comprise a software tool that may interface (via a connector, not shown) with the PDI software 10. The software of the requirements definition tool 12 may comprise a single application, or may comprise a combination of applications (e.g., a commercially available application suite or other combination of interrelated applications). The requirements definition tool 12 may be used to define requirements for an engineering project and may output design data that comprises data elements describing those requirements. The requirements definition tool 12 may be software that is not an extension of, and is not native to, the PDI software 10, and/or that is not provided by the provider of the PDI software 10. An example of software that may be used for the requirements definition tool 12 is the IBM® Engineering Requirements Management DOORS® Next software provided by International Business Machines Corporation of Armonk, NY, US.

System architecture (sys. arch.) tool 14 may comprise a software tool that may interface (via a connector, not shown) with the PDI software 10. The software of the system architecture tool 14 may comprise a single application, or may comprise a combination of applications (e.g., a commercially available application suite or other combination of interrelated applications). The system architecture tool 14 may be used to define a system architecture for an engineering project and may output design data that comprises data elements describing that system architecture. The system architecture tool 14 may be software that is not an extension of, and is not native to, the PDI software 10, and/or that is not provided by the provider of the PDI software 10. Examples of software that may be used for the system architecture tool 14 are the CAMEO ENTERPRISE ARCHITECTURE software provided by Dassault Systèmes of Vélizy-Villacoublay, FR and/or the IBM® Rational® Rhapsody® software provided by International Business Machines Corporation.

Virtual implementation (virt. impl.) tool 16 may comprise software that may interface (via a connector, not shown) with the PDI software 10. The software of the virtual implementation tool 16 may comprise a single application, or may comprise a combination of applications (e.g., a commercially available application suite or other combination of interrelated applications). The virtual implementation tool 16 may be used to create detailed virtual models of components and/or subsystems, and/or of an entire system. The virtual implementation tool 16 may output design data that comprises data elements describing those detailed virtual models. The virtual implementation tool 16 may be software that is not an extension of, and is not native to, the PDI software 10, and/or that is not provided by the provider of the PDI software 10. Example software that may be used for the virtual implementation tool 16 are the Solidworks® software provided by Dassault Systèmes SolidWorks Corporation of Waltham, MA, US and/or the NX software provided by Siemens Industry Software Inc. of Plano, TX, US.

Simulation/test (sim./test) tool 18 may comprise software that may interface (via a connector, not shown) with the PDI software 10. The software of the simulation/test tool 18 may comprise a single application, or may comprise a combination of applications (e.g., a commercially available application suite or other combination of interrelated applications). The simulation/test tool 18 may be used to simulate use of, and/or the effects of physical phenomena on, physical elements that are represented by virtual models of components and/or subsystems, and/or of an entire system. The simulation/test tool 18 may also or alternatively be used to conduct and/or document tests on physical elements. The simulation/test tool 18 may output design data that comprises data elements describing results of simulations and/or other virtual tests of modelled components, sub-systems or an entire system, as well as data elements describing actual tests. The simulation/test tool 18 may be software that is not an extension of, and is not native to, the PDI software 10, and/or that is not provided by the provider of the PDI software 10. Example software that may be used for the simulation/test tool 18 are the MATLAB® software provided by The Math Works, Inc. of Natick, MA, US, the AGI STK software provided by Ansys, Inc. of Canonsburg, PA, US, the AGI Systems Tool Kit software provided by Ansys, Inc., the AFSIM (Advanced Framework for Simulation, Integration and Modeling) software provided by the United States government (the United States Air Force Research Laboratory), and/or the ModelCenter® software and the ModelCenter® MBSE software provided by Ansys, Inc.

Acceptance testing (Accept. test) tool 20 may comprise a software tool that may interface (via a connector, not shown) with the PDI software 10. The software of the acceptance testing tool 20 may comprise a single application, or may comprise a combination of applications (e.g., a commercially available application suite or other combination of interrelated applications). The acceptance testing tool 20 may be used to generate documentation for acceptance testing and/or to track acceptance testing data, and may output design data that comprises data elements associated with acceptance testing. The acceptance testing tool 20 may be software that is not an extension of, and is not native to, the PDI software 10, and/or that is not provided by the provider of the PDI software 10.

Technical documentation (Tech. doc.) tool 22 may comprise a software tool that may interface (via a connector, not shown) with the PDI software 10. The software of the technical documentation tool 22 may comprise a single application, or may comprise a combination of applications (e.g., a commercially available application suite or other combination of interrelated applications). The technical documentation tool 22 may be used to generate manuals and/or other documentation to describe operation of, repair or, use of, and/or other characteristics of a system (or component thereof) that is designed using tools of the digital engineering ecosystem of FIG. 1, and may output design data that comprises data elements associated with such manuals and/or other technical documentation. The technical documentation tool 22 may be software that is not an extension of, and is not native to, the PDI software 10, and/or that is not provided by the provider of the PDI software 10.

Manufacturing tool (Mfg.) tool 24 may comprise a software tool that may interface (via a connector, not shown) with the PDI software 10. The software of the manufacturing tool 24 may comprise a single application, or may comprise a combination of applications (e.g., a commercially available application suite or other combination of interrelated applications). The manufacturing tool 24 may be used to generate and/or track data associated with manufacturing a system (or component thereof) that is designed using tools of the digital engineering ecosystem of FIG. 1, and may output design data that comprises data elements associated with such manufacturing. The manufacturing tool 24 may be software that is not an extension of, and is not native to, the PDI software 10, and/or that is not provided by the provider of the PDI software 10.

Sustainment/Maintenance tool (Sust./Maint.) tool 26 may comprise a software tool that may interface (via a connector, not shown) with the PDI software 10. The software of the sustainment/maintenance tool 26 may comprise a single application, or may comprise a combination of applications (e.g., a commercially available application suite or other combination of interrelated applications). The sustainment/maintenance tool 26 may be used to generate and/or track data associated with engineering changes and/or other modifications to a system (or component thereof) that is designed using tools of the digital engineering ecosystem of FIG. 1, and may output design data that comprises data elements associated with such changes and/or modifications. The sustainment/maintenance tool 26 may be software that is not an extension of, and is not native to, the PDI software 10, and/or that is not provided by the provider of the PDI software 10.

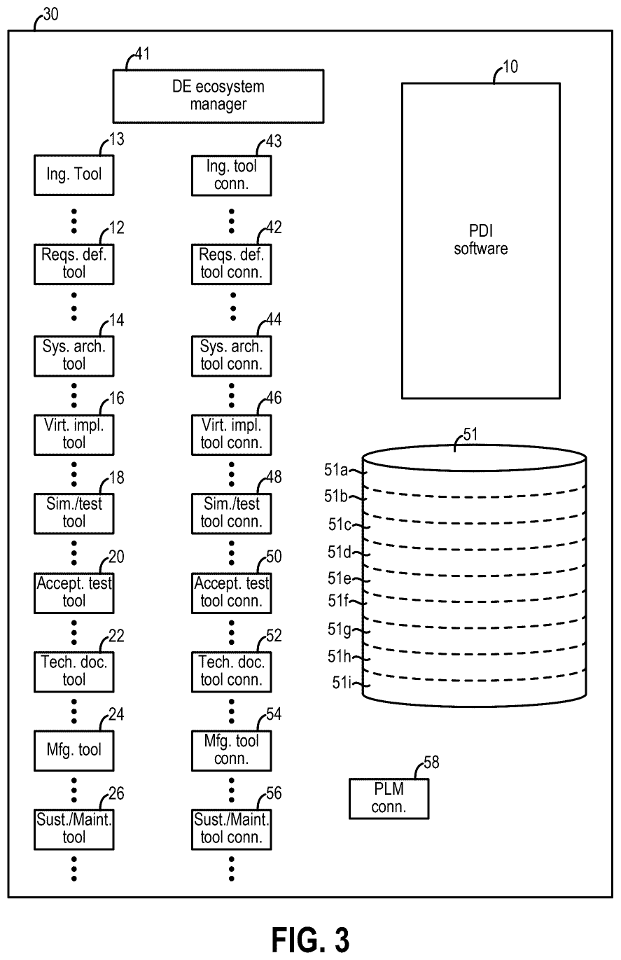

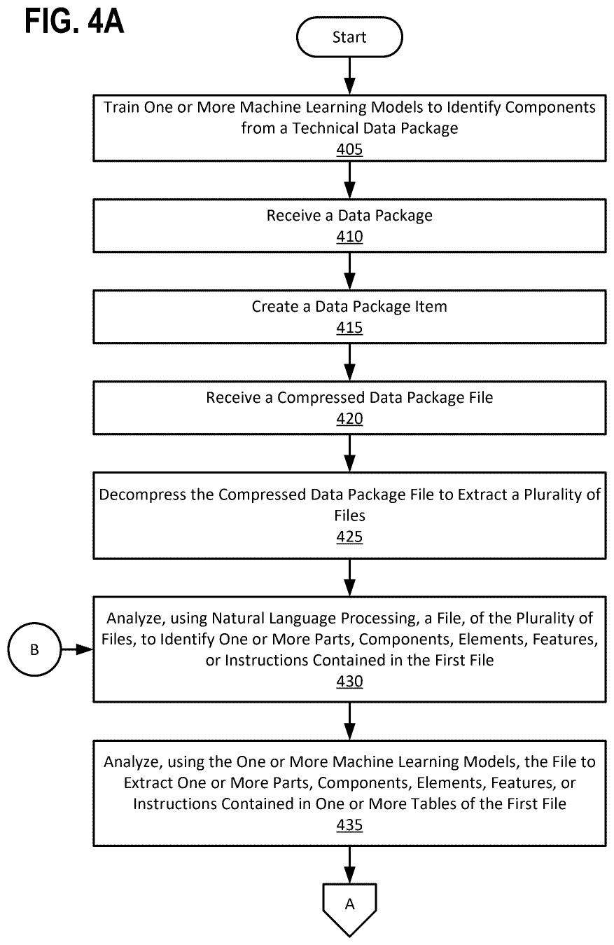

FIG. 2 shows an example network in which an example DE ecosystem may be implemented in accordance with one or more aspects of the disclosure. Software of a DE ecosystem may be hosted on, and be executed by, a computing system 30. As described in more detail in connection with FIG. 3 below, such software may comprise the PDI software 10, the tools 12, 14, 16, 18, 20, 22, 24, and 26, corresponding connectors, and additional software components. Although shown as a single block in FIG. 2 for convenience, the computing system 30 may comprise a single computing device or may comprise multiple computing devices. If implemented as multiple computing devices, the computing devices of the computing system 30 may communicate via one or more local or wide area networks (e.g., the network 33 described below), and may or may not be in close proximity of one another. Multiple computing devices of the computing system 30 may distribute computational tasks associated with the DE ecosystem software in any manner, and/or may host some or all of that software in one or more virtual servers. The computing system 30 may, for example, comprise computing devices associated with a cloud computing platform such as Amazon Web Services® cloud computing hosting services.

The computing system 30 may communicate, via one or more networks 33, with one or more computing devices such as the computing devices 35 through 38. Each of the computing devices 35 through 38, and/or other computing devices not shown in FIG. 2, may be associated with a user and may be used to access DE ecosystem software hosted on the computing system 30. Each of the computing devices 35 through 38, and/or other computing devices, may comprise a laptop computer, a desktop computer, and/or other type of computer comprising web browser software that may be used to access the DE ecosystem software. The network 33 may comprise the Internet and/or other wide area data network, a local area data network, or a combination of data networks.

FIG. 3 is a diagram showing example DE ecosystem software hosted on the computing system 30. The software may comprise the requirements definition tool 12, a requirements definition tool connector 42, the ingestion tool 13, an ingestion tool connector 43, the system architecture tool 14, a system architecture tool connector 44, the virtual implementation tool 16, a virtual implementation tool connector 46, the simulation/test tool 18, a simulation/test tool connector 48, the acceptance testing tool 20, an acceptance testing tool connector 50, the technical documentation tool 22, a technical documentation tool connector 52, the manufacturing tool 24, a manufacturing tool connector 54, the sustainment/maintenance tool 26, a sustainment/maintenance tool connector 56, a PLM connector 58, the PDI software 10, and a DE ecosystem manager 41.

As also shown in FIG. 3, the computing system 30 may comprise a database 51 having one or more portions used to store certain types of data. For example, a first portion 51a of the database 51 may be used to store requirements data for a project, such as data output by the requirements definition tool 12. A second portion 51b of the database 51 may be used to store system architecture data for a project, such as data output by the system architecture tool 14 or ingestion tool 13. A third portion 51c of the database 51 may be used to store virtual implementation data for a project, such as data output by the virtual implementation tool 16. A fourth portion 51d of the database 51 may be used to store simulation/test data for a project, such as data output by the simulation/test tool 18. A fifth portion 51e of the database 51 may be used to store acceptance testing data for a project, such as data output by the acceptance testing tool 20. A sixth portion 51f of the database 51 may be used to store technical documentation data for a project, such as data output by the technical documentation tool 22. A seventh portion 51g of the database 51 may be used to store manufacturing data for a project, such as data output by the manufacturing tool 24. An eighth portion 51h of the database 51 may be used to store sustainment/maintenance data for a project, such as data output by the sustainment/maintenance tool 26. A ninth portion 51i of the database 51 may be used to store project data output by the PDI software 10. That project data may correspond to, and may integrate, data output by the tools 12, 13, 14, 16, 18, 20, 22, 24, and 26. For example, the project data may map (or otherwise link) data elements of data in one or more the database portions 51a through 51h with data elements of data in one or more other database portions 51a through 51h. Although a single database 51 is shown in FIG. 3 for simplicity, multiple databases (e.g., implemented by multiple computing devices of the computing system 30) may be used to store data such as that described herein.

The requirements definition tool connector 42 may receive data output by the requirements definition tool 12. That output data may comprise data elements, generated by the requirements definition tool 12 based on inputs from the users of the requirements definition tool 12, that make up requirements defined for a project. The project requirements may be stored in the database portion 51a, as indicated above. However, at least a portion of the output data from the requirements definition tool 12 may be used to generate project data output by the PDI software 10. In particular, the requirements definition tool connector 42 may receive data output by the requirements definition tool 12 and may process at least a portion of that data to generate input data for the PDI software 10. Based on that input data, which the PDI software 10 may receive from the connector 42, the PDI software 10 may generate project data and store that project data in the database portion 51i.

The ingestion tool connector 43 may receive output from the ingestion tool 13. That output data may comprise parts, components, elements, features, instructions, and the like, generated by the ingestion tool 13 based on analysis of one or more files contained in a technical data package associated with a project. The parts, components, elements, features, instructions, and the like may be stored in the database portion 51a, as indicated above. However, at least a portion of the output data from the ingestion tool 13 may be used to generate project data output by the PDI software 10. In particular, the ingestion tool connector 43 may receive data output by the ingestion tool 13 and may process at least a portion of that data to generate input data for the PDI software 10. Based on that input data, which the PDI software 10 may receive from the connector 43, the PDI software 10 may generate project data and store that project data in the database portion 51i.

The system architecture tool connector 44 may receive data output by the system architecture tool 14. That output data may comprise data elements, generated by the system architecture tool 14 based on inputs from the users of the system architecture tool 14, that make up a system architecture for the project. The project system architecture may be stored in the database portion 51b, as indicated above. However, at least a portion of the output data from the system architecture tool 14 may be used to generate project data output by the PDI software 10. In particular, the system architecture tool connector 44 may receive data output by the system architecture tool 14 and may process at least a portion of that data to generate input data for the PDI software 10. Based on that input data, which the PDI software 10 may receive from the connector 44, the PDI software 10 may generate project data and store that project data in the database portion 51i.

The virtual implementation tool connector 46 may receive data output by the virtual implementation tool 16. That output data may comprise data elements, generated by the virtual implementation tool 14 based on inputs from the users of the virtual implementation tool 16, that make up virtual models of components and/or subsystems (and/or the entire system) for the project. The virtual implementation data may be stored in the database portion 51c, as indicated above. However, at least a portion of the output data from the virtual implementation tool 16 may be used to generate project data output by the PDI software 10. In particular, the virtual implementation tool connector 46 may receive data output by the virtual implementation tool 16 and may process at least a portion of that data to generate input data for the PDI software 10. Based on that input data, which the PDI software 10 may receive from the connector 46, the PDI software 10 may generate project data and store that project data in the database portion 51i.

The simulation/test tool connector 48 may receive data output by the simulation/test tool 18. That output data may comprise data elements, generated by the simulation/test tool 18 based on inputs from the users of the simulation/test tool 18, that make up data for simulations performed on virtual models of components and/or subsystems (and/or the entire system) for the project and/or tests performed on physical elements. That simulation/test data may comprise results of the simulations and/or tests, configurations of simulations and/or tests (e.g., parameters and/or data models used), animations and/or other graphical or audio data generated during a simulation or test, and/or other types of data. The simulation/test data may be stored in the database portion 51d, as indicated above. However, at least a portion of the output data from the simulation/test tool 18 may be used to generate project data output by the PDI software 10. In particular, the simulation/test tool connector 48 may receive data output by the simulation/test tool 18 and may process at least a portion of that data to generate input data for the PDI software 10. Based on that input data, which the PDI software 10 may receive from the connector 48, the PDI software 10 may generate project data and store that project data in the database portion 51i.

The acceptance testing tool connector 50 may receive data output by the acceptance testing tool 20. That output data may comprise data elements, generated by the acceptance testing tool 20 based on inputs from the users of the acceptance testing tool 20, that make up acceptance testing data for a project. The acceptance testing data may be stored in the database portion 51c, as indicated above. However, at least a portion of the output data from the acceptance testing tool 20 may be used to generate project data output by the PDI software 10. In particular, the acceptance testing tool connector 50 may receive data output by the acceptance testing tool 20 and may process at least a portion of that data to generate input data for the PDI software 10. Based on that input data, which the PDI software 10 may receive from the connector 50, the PDI software 10 may generate project data and store that project data in the database portion 51i.

The technical documentation tool connector 52 may receive data output by the technical documentation tool 22. That output data may comprise data elements, generated by the technical documentation tool 22 based on inputs from the users of the technical documentation tool 22, that make up technical documentation data for a project. The technical documentation data may be stored in the database portion 51f, as indicated above. However, at least a portion of the output data from the technical documentation tool 22 may be used to generate project data output by the PDI software 10. In particular, the technical documentation tool connector 52 may receive data output by the technical documentation tool 22 and may process at least a portion of that data to generate input data for the PDI software 10. Based on that input data, which the PDI software 10 may receive from the connector 52, the PDI software 10 may generate project data and store that project data in the database portion 51i.

The manufacturing tool connector 54 may receive data output by the manufacturing tool 24. That output data may comprise data elements, generated by the manufacturing tool 24 based on inputs from the users of the manufacturing tool 24, that make up manufacturing data for a project. The manufacturing data may be stored in the database portion 51g, as indicated above. However, at least a portion of the output data from the manufacturing tool 24 may be used to generate project data output by the PDI software 10. In particular, the manufacturing tool connector 54 may receive data output by the manufacturing tool 24 and may process at least a portion of that data to generate input data for the PDI software 10. Based on that input data, which the PDI software 10 may receive from the connector 54, the PDI software 10 may generate project data and store that project data in the database portion 51i.

The sustainment/maintenance tool connector 56 may receive data output by the sustainment/maintenance tool 26. That output data may comprise data elements, generated by the sustainment/maintenance tool 26 based on inputs from the users of the sustainment/maintenance tool 26, that make up sustainment/maintenance data for a project. The sustainment/maintenance data may be stored in the database portion 51h, as indicated above. However, at least a portion of the output data from the sustainment/maintenance tool 26 may be used to generate project data output by the PDI software 10. In particular, the sustainment/maintenance tool connector 56 may receive data output by the sustainment/maintenance tool 26 and may process at least a portion of that data to generate input data for the PDI software 10. Based on that input data, which the PDI software 10 may receive from the connector 56, the PDI software 10 may generate project data and store that project data in the database portion 51i.

As indicated by the vertical ellipses under the requirements definition tool 12 and the requirements definition tool connector 42, the DE ecosystem may comprise more than one requirement definition software tool and corresponding connector. Similarly, and as shown by the other ellipses, the DE ecosystem may comprise more than one system architecture software tool and corresponding connector, more than one virtual implementation software tool and corresponding connector, more than one simulation/test software tool and corresponding connector, more than one acceptance testing software tool and corresponding connector, more than one technical documentation software tool and corresponding connector, more than one manufacturing software tool and corresponding connector, and/or more than one sustainment/maintenance software tool and corresponding connector. For example, the DE ecosystem may be configured to allow a group of users to select which tool of each type that the group prefers. In addition to the types of tools shown in FIG. 3, the DE ecosystem may also comprise other types of tools and corresponding connectors. For example, the DE ecosystem may comprise a PLM connector 58. The PLM connector 58 may interface the PDI software 10 and a separate (e.g., legacy) PLM system.

In addition to accessing the tools 12, 14, 16, 18, 20, 22, 24, and/or 26 (and/or other tools), users may also access the PDI software 10. For example, users may access the PDI software 10 to determine one or more requirements, generated using the requirements tool 12, related to data associated with one or more of the tools interfacing with the PDI software 10 (e.g., one or more portions of the system architecture, one or more virtual models, one or more simulations and/or tests, one or portions of acceptance testing data, one or more portion of technical documentation data, one or more portions of manufacturing data, one or more portions of sustainment/maintenance data, and/or to other types of data). In general, users may access the PDI software 10 to determine one or more portions of data, associated with any of the tools 12, 14, 16, 20, 22, 24, and/or 26 (and/or other tools), that may be related to any other data associated with any of the tools 12, 14, 16, 20, 22, 24, and/or 26 (and/or other tools).

The DE ecosystem manager 41 may comprise software to perform operations associated with providing users access to the DE ecosystem. For example, the DE ecosystem manager 41 may control login, verification and/or authentication of users, access control (e.g., limiting data available to specific users or groups of users), and other types of operations. The DE ecosystem manager 41 may monitor users' access (e.g., tools accessed, direct access of the PDI software 10, duration of login time or other temporal measure of access, amount of data transferred, etc.), and/or provide information from this monitoring for use in billing for access to the DE ecosystem. The DE ecosystem manager 41 may also or alternatively control instantiation of the DE ecosystem or portions thereof and/or access to an already-instantiated DE ecosystem or portions thereof. For example, the DE ecosystem manager 41 may comprise software configured to carry out operations such as those described below.

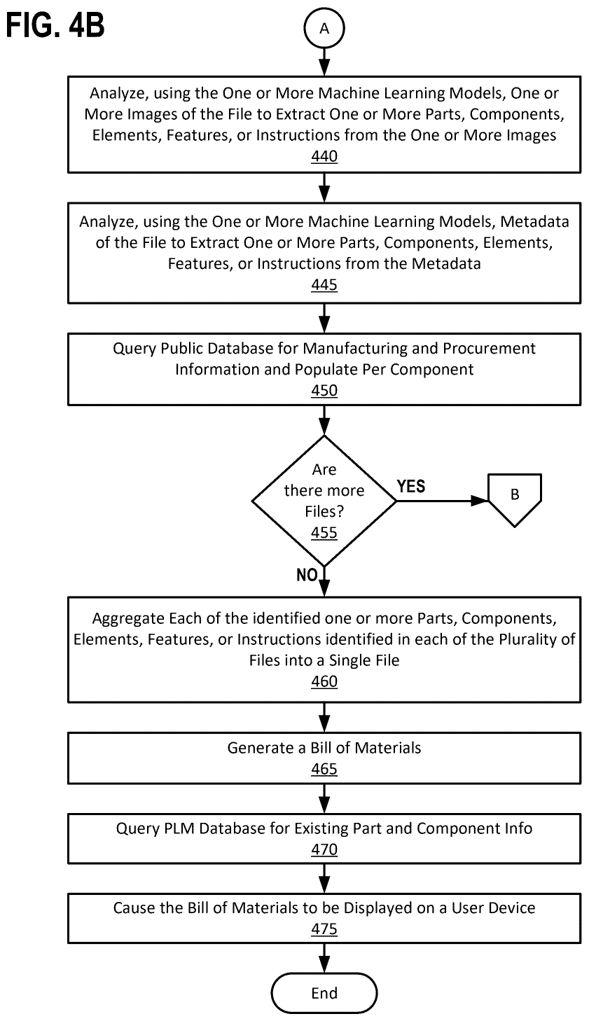

As noted above, the DE ecosystem may need to ingest one or more technical data packages (TDPs) associated with an engineering product. FIGS. 4A and 4B show an example process for ingesting a plurality of a plurality of files associated with a technical data package in accordance with one or more aspects of the disclosure. Some or all of the steps of the process shown in FIGS. 4A and 4B may be performed using one or more computing devices as described herein.

In step 405, a computing device may train one or more machine learning models to analyze one or more files to identify one or more parts, components, elements, features, or instructions contained therein. The one or more machine learning models may comprise a large language model (LLM). Additionally or alternatively, the one or more machine learning models may comprise a neural network, such as a convolutional neural network (CNN), a recurrent neural network, a recursive neural network, a long short-term memory (LSTM), a gated recurrent unit (GRU), an unsupervised pre-trained network, a space invariant artificial neural network, a generative adversarial network (GAN), or a consistent adversarial network (CAN), such as a cyclic generative adversarial network (C-GAN), a deep convolutional GAN (DC-GAN), GAN interpolation (GAN-INT), GAN-CLS, a cyclic-CAN (e.g., C-CAN), or any equivalent thereof. Additionally or alternatively, the one or more machine learning model may comprise one or more decision trees. The one or more machine learning models may be trained using supervised learning, unsupervised learning, back propagation, transfer learning, Adam stochastic optimization, stochastic gradient descent, learning rate decay, dropout, max pooling, batch normalization, long short-term memory, skip-gram, or any equivalent deep learning technique. The one or more machine learning models may be trained, for example, using technical data packages comprising bills of material. A corpus of the training data set may be divided into training data and testing data. Preferably, 65% to 85% of the corpus would form the training data, while the remaining 15% to 35% of the corpus would be test data. The one or more machine learning models may be trained using the training data, while the test data would be used to help the machine learning model achieve convergence (i.e., an error range with an acceptable tolerance). Once the one or more machine learning models are trained to analyze one or more files to identify one or more parts, components, elements, features, or instructions contained therein, the one or more trained machine learning model may be deployed, for example, as part of a DE ecosystems and/or a PLM tool.

In step 410, a computing device may receive a data package. In particular, a PLM tool executing on the computing device may receive the data package. The data package may be uploaded and/or imported into the PLM tool Additionally or alternatively, a user may create a new data package via one or more interfaces of the PLM tool.

In step 415, the computing device may generate a data package item associated with the received data package. Generating the data package item may comprise assigning a name to the data package item, writing a description of the data package item, indicating an owner of the data package item, inputting a date the data package item was received with the one or more data packages, inputting a time the data package item was received with the one or more data packages, etc.

In step 420, the computing device may receive a compressed data package file associated with the data package item. The compressed data package file may comprise a technical data package (TDP). As noted above, a TDP may comprise a set of electronic files that describes a product or item. The set of electronic files may comprise 3D models, CAD drawings, product manufacturing information (PMI), bills of material (BOMs), a plurality of files indicating one or more parts, components, elements, features, or instructions associated with an engineering design, and any other necessary data. In some instances, the compressed data package (e.g., TDP) comprises an archive file, such as a ZIP file. The compressed data package file may be uploaded to and/or imported into the PLM tool.

In step 425, the computing device may decompress the compressed data package file to extract the plurality of files contained therein. Decompressing the compressed data package file may comprise unzipping the compressed data package file. In other words, a plurality of files may be extracted from the compressed data package file and stored (e.g., saved) in a new location, such as new folder or a new directory.

In step 430, the computing device may analyze a text of a first file. The first file may be one of the plurality of files extracted from the compressed data package file. The analysis of the text may be performed via an automated analysis of the first file. The automated analysis may comprise natural language processing (NLP), object character recognition (OCR), computer vision, or any suitable document analysis algorithm The analysis may be configured to identify one or more parts, components, elements, features, or instructions contained in the first file. The analysis may remove duplicate, or repeated, parts, components, elements, features, instructions, etc., aggregate a total number of each part, component, element, feature, etc., and identify any gaps or missing parts, components, elements, features, and/or instructions. The analysis may also generate a confidence score associated with each of the identified parts, components, elements, features, instructions, and the like. Based on the analysis, the identified parts, components, elements, features, or instructions may be saved to (e.g., stored in) a file, such as a CSV, a JSON, a spreadsheet, a word processing document, or any other suitable document. Any gaps and/or missing parts, components, elements, features, instructions, etc. may also be saved to the file. Duplicate parts, components, elements, features, instructions, etc. may also be included in the file. Finally, each of the parts, components, elements, features, instructions, etc. identified in the file, as well as any identified gaps and/or duplicate parts, may have a confidence score associated therewith. As noted above, the confidence score may indicate the probability or likelihood that the identified part, component, element, feature, and/or instruction is accurate and/or correct.

In step 435, the computing device may analyze one or more tables of the first file. The analysis of the one or more tables may be performed using a first machine learning model, such as any of the machine learning models described above. The first machine learning model may be configured to analyze one or more tables contained in the first file and extract one or more parts, components, elements, features, or instructions contained in each of the tables of the first file. The extracted parts, components, elements, features, or instructions may be saved to (e.g., stored in) the file discussed above with respect to step 430. Additionally or alternatively, the extracted parts, components, elements, features, or instructions may be saved to (e.g., stored in) a different file.

In step 440, the computing device may analyze one or more images contained in the first file. The one or more images may comprise engineering drawings, schematics, exploded views of parts, etc. The analysis of the one or more images may be performed using a second machine learning model configured to analyze images and identify individual components and parts contained in each of the one or more images. The second machine learning model may be any suitable machine learning model described above. As a preliminary step, the second machine learning model may identify a type of each drawing. In this regard, each type of drawing may contain information pertinent to generating the bill of materials. For instance, a Procurement Control Drawing may include performance requirements of parts to be acquired, including dimensioning and/or other information critical to future replacement components, a Vendor Item Control Drawing may provide information associated with listed suppliers delineating the limits to which replacement parts may vary from the original specifications. It generally keeps control of the paper trail, and a Source Control Drawing may provide engineering data regarding design requirements and limitations of acceptable replacement parts, along with a list of approved suppliers of parts. Generally, parts are not permitted to be sourced an unlisted supplier. These drawing may comprise additional part numbers and sources that should be identified and add data to the hierarchy stored in the BOM. Based on the analysis, the second machine learning model may be configured to identify one or more parts, components, elements, features, or instructions contained the one or more drawings and export the one or more parts, components, elements, features, or instructions to the file discussed above with respect to step 430. Additionally or alternatively, the identified parts, components, elements, features, or instructions may be saved to (e.g., stored in) a different file.

In step 445, the computing device may analyze the first file for metadata. The analysis of the metadata may be performed using a third machine learning model, such as any of the machine learning models described above. The third machine learning model may be configured to analyze metadata contained in the first file and extract one or more parts, components, elements, features, or instructions contained in the metadata of the first file. The extracted parts, components, elements, features, or instructions may be saved to (e.g., stored in) the file discussed above with respect to step 430.

While the descriptions above describe various analyses performed on the first file to identify one or more parts, components, elements, features, or instructions, it will be appreciated that the various steps may not be applicable to each of the files contained in the plurality of files. Accordingly, a skilled artisan would understand that one or more of the steps discussed above may be skipped based on the type of file. For example, a CAD drawing may have limited text and the text analysis described above may be skipped. In another example, an unstructured data file may not have metadata, and the metadata analysis with respect to step 445 may be skipped for unstructured data files.

In step 450, the computing device may query a database, such as database 51 or another database associated with PLM tool 510 (e.g., a PLM database), to obtain manufacturing and procurement information populate any components or assemblies with existing information from the items in the database. In other words, the computing device (e.g., PLM tool executing on the computing device) may identify the availability of each of the parts, components, elements, features, instructions, etc. The computing device may also flag any parts, components, elements, features, instructions, etc. that are determined to be obsolete. Further, the computing device may be configured to find and populate each component row with planned obsolescence information, manufacturer information, distributor(s) information, release dates, site links, and/or any other specifications.

In step 455, the computing device may determine whether there are any files, in the plurality of files that were extracted from the compressed data package file, that have not been analyzed to identify one or more parts, components, elements, features, or instructions contained therein. If there are files that have not been analyzed, the process shown in FIGS. 4A and 4B may return to step 430. The analysis described above with respect to steps 430, 435, 440, and/or 445 may be repeated for each of the plurality of files that were extracted from the compressed data package file. When each of the plurality of files extracted from the compressed data package file have been analyzed (i.e., there are no more files to analyze), the process may proceed to step 455.

In step 460, the computing device may aggregate each of the identified one or more parts, components, elements, features, or instructions identified in each of the plurality of files, as well as the manufacturing and procurement information, into a single file. The single file may comprise a spreadsheet, or table, of identified parts, components, and/or elements. Additionally or alternatively, the single file may comprise additional features and/or a compilation of instructions. Each row of the spreadsheet may identify the part, component, and/or element, as well as manufacturer information, obsolescence information, distributor(s) information, release date(s), site links, and/or any other specifications associated with the identified part, component, and/or element. As part of the aggregation process, the computing device may determine whether any of the identified one or more parts, components, elements, features, or instructions are duplicated. If the computing device determines that at least one of the identified one or more parts, components, elements, features, or instructions are duplicated, the computing device may send an electronic communication to a user device. The electronic communication may indicate the one or more duplicated parts, components, elements, features, or instructions. The computing device may receive a response to the electronic communication. The response may confirm the duplicate parts, components, elements, features, or instructions. Accordingly, the computing device may remove (e.g., delete) the duplicate parts, components, elements, features, or instructions from the single file. Removing (e.g., deleting) parts, components, elements, features, or instructions from the single file may be based on, or in response to, receiving authorization to remove (e.g., delete) duplicate, or repeated, parts, components, elements, features, instructions, etc. Alternatively, the response may indicate that there are no duplicates, and the computing device may include all of the parts, components, elements, features, or instructions identified in the analysis describe above. Additionally or alternatively, the computing device may remove one or more duplicated parts, components, elements, features, or instructions from the single file, for example, based on a determination that at least one of the identified one or more parts, components, elements, features, or instructions are duplicated.

According to some aspects of the disclosure, the computing device may correlate each of the one or more parts, components, elements, features, or instructions identified during the text analysis with the one or more parts, components, elements, features, or instructions identified during the image analysis, for example, prior to aggregating each of the identify one or more parts, components, elements, features, or instructions identified in each of the plurality of files into the single file. This correlation may identify one or more missing parts, components, elements, features, or instructions, for example, if there is not a one-to-one correlation between each of the parts, components, elements, features, or instructions identified during a first analysis of the first file (e.g., a text analysis of the first file) and the parts, components, elements, features, or instructions identified during a second analysis of the first file (e.g., an image analysis of the first file). When one or more missing parts, components, elements, features, or instructions are identified, the computing device may send an electronic communication to the user device. The electronic communication may indicate the one or more missing parts, components, elements, features, or instructions.

According to additional aspects of the disclosure, the computing device may compile a list of instructions for assembling one or more parts, components, elements, or features, for example, based on identifying a plurality of instructions in each of the plurality of files. Compiling the list of instructions may be an additional aspect of the aggregation process performed in step 455.

In step 465, the computing device may generate a bill of materials, for example, based on the one or more parts, components, elements, features, or instructions aggregated in the single file. A bill of materials (BOM) is a centralized source of information used to manufacture a product. The BOM is a list of the items needed to create a product, as well as, the instructions on how to assemble that product. The BOM may allow manufacturers to start an assembly and/or manufacturing process once the BOM is generated.

In step 470, the computing device may query a database, such as database 51 or another database associated with PLM tool 510 (e.g., a PLM database), for existing part and/or component information. In other words, the computing device (e.g., PLM tool executing on the computing device) may query the database to identify the availability of each of the parts, components, elements, features, instructions, etc.; flag any obsolete parts, components, elements, features, instructions, etc. for user review; and find and populate each component row with planned obsolescence information, manufacturer information, distributor(s) information, release dates, site links, and/or any other specifications. Additionally or alternatively, the computing device may verify (e.g., authenticate, validate, etc.) the information obtained by the one or more machine learning models based on querying the database. In yet a further example, the computing device may identify additional properties, such as revision information, classification information, state information, distribution code, owner information, etc. The additional properties may populate each component row with the additional information identified by querying the database.

In step 475, the computing device may cause the BOM to be displayed on a user device. In some instances, the computing device may send an electronic communication (e.g., email, text message, push notification, etc.), containing the BOM, to a user device. In other instances, the computing device may cause the BOM to be displayed via one or more interfaces of the PLM tool.

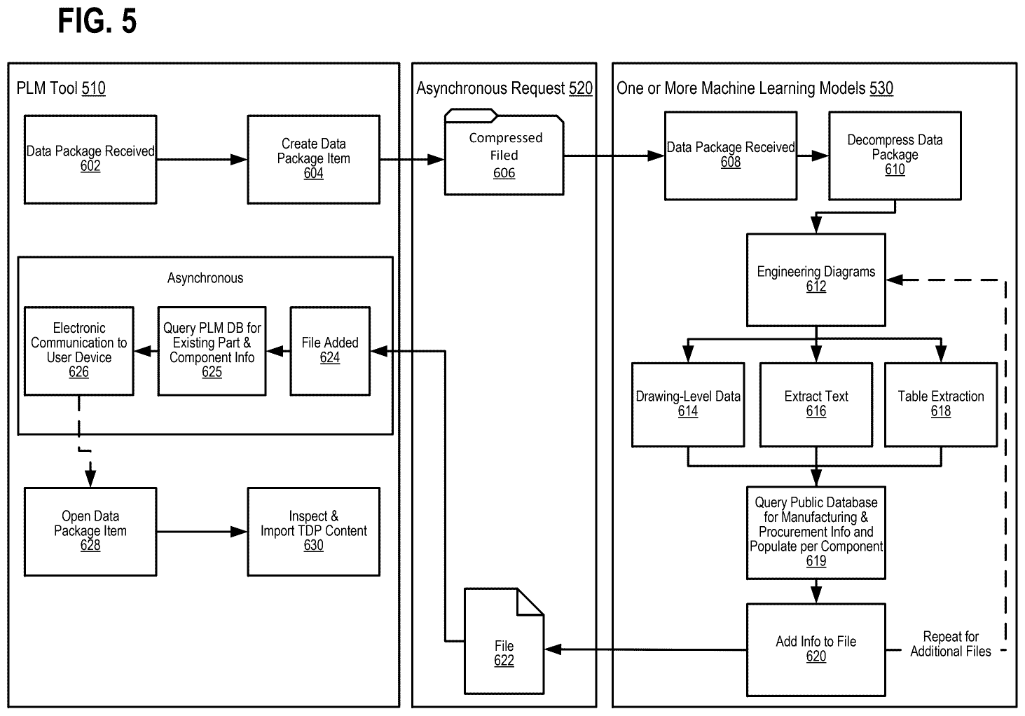

FIG. 5 shows an example of ingesting a plurality of files using the product lifecycle management tool and the one or more machine learning models in accordance with one or more aspects of the disclosure. In particular, FIG. 5 shows PLM tool 510 and one or more machine learning models 530. As shown in FIG. 5, PLM tool 510 may make one or more asynchronous requests 520 to the one or more machine learning models.

PLM tool 510 may receive a data package, for example, in step 602. After receiving the data package, the PLM tool 510 may create a data package item. As noted above, creation of the data package item may include defining a name of the data package item, a description of the data package item, an owner of the data package item, a date the data package item was received with the one or more data packages, or a time the data package item was received with the one or more data packages. Additionally or alternatively, the creation of the data package item may comprise the addition of a compressed file. The compressed file, referred to as a compressed data package file above, may comprise a TDP. Further to the discussion above, the compressed file may be uploaded, or imported, to PLM tool 510.

In step 606, a request may be made to analyze the files contained in the compressed file. The request may be an asynchronous request. In step 608, the one or more machine learning models 530 may receive a data package. The data package may include the compressed file. In step 610, the computing device may decompress the data package. As noted above with respect to step 420, decompressing the data package may comprise unzipping a plurality of files from the compressed file.

After unzipping the plurality of files, one or more different analyses may be applied to each of the plurality of files. In step 612, one or more engineering diagrams may be analyzed to identify one or more parts, components, elements, features, or instructions contained in the engineering diagrams. The one or more engineering diagrams may be analyzed using the one or more machine learning algorithms, discussed above. In step 614, drawing-level data may be analyzed, using the one or more machine learning models, to identify one or more parts, components, elements, features, or instructions. In step 616, text associated with one or more parts, components, elements, features, or instructions may be extracted from a file. The text may be extracted using the one or more machine learning models. In step 618, one or more parts, components, elements, features, or instructions may be extracted from one or more tables included in the plurality of files. As shown in FIG. 5, steps 614, 616, and 618 may be performed in parallel. Alternatively, steps 614, 616, and 618 may be performed serially. As noted above, a confidence score may be associated with each of the identified parts, components, elements, features, or instructions. The confidence score may comprise a probability, or likelihood, that the identified part, component, element, feature, and/or instruction is accurate and/or correct.

The information gleaned from the analyses in steps 612, 614, 616, and 618 may be used to query a database. In step 619, the one or more machine learning models 530 may query a public database for manufacturing and procurement information. According to some instances, querying the public database may be used to identify the availability of each of the parts, components, elements, features, instructions, etc. The one or more machine learning models 530 may also flag any obsolete parts, components, elements, features, instructions, etc. for user review. Additionally or alternatively, the one or more machine learning models 530 may find and populate each component row with planned obsolescence information, manufacturer information, distributor(s) information, release dates, site links, and/or any other specifications the one or more machine learning models may find. In step 620, the information gleaned in steps 612, 614, 616, 618, and 619 may be added to a file. If there are additional files that need to be analyzed, the process may return to step 612. If all of the files have been analyzed, the information obtained from the analysis may be written to a file, in step 622. As noted above, the file may be a CSV, a JSON, a spreadsheet, a word processing document, or any other suitable document.

In step 624, the file may be associated with the data package item. That is, the file may be added to the folder and/or directory contain information associated with the data package. In step 625, PLM tool 510 may query a database, such as database 51 or another database associated with PLM tool 510 (e.g., a PLM database), to populate any components or assemblies with existing information from the items in the database. That is, the PLM tool 510 may identify the availability of each of the parts, components, elements, features, instructions, etc.; flag any obsolete parts, components, elements, features, instructions, etc. for user review; and find and populate each component row with planned obsolescence information, manufacturer information, distributor(s) information, release dates, site links, and/or any other specifications. Additionally or alternatively, PLM tool 510 querying the database may be used to verify (e.g., authenticate, validate, etc.) the information obtained by the one or more machine learning models, in step 619 above. Further, PLM tool 510 may also identify additional properties, such as revision information, classification information, state information, distribution code, owner information, etc. The additional properties may populate each component row with the additional information identified by querying the PLM database. In step 626, an electronic communication may be provided to the user device. The electronic communication may be an email, a text message, a push notification, etc. In step 628, an owner of the data package may open the file. The owner may edit the file. Once the owner has completed their review of the file, the PLM tool may receive an electronic communication indicating approval of the file. Upon receiving approval, the contents of the file may be uploaded (e.g., imported) into a database, for example, in step 630. The upload (e.g., import) may save each of the parts, components, elements, features, instructions, etc. identified in the analysis to the database. In some instances, the database may identify relationships between the parts, components, elements, features, instructions, etc. The file may then be used to generate a bill of materials, as described above.

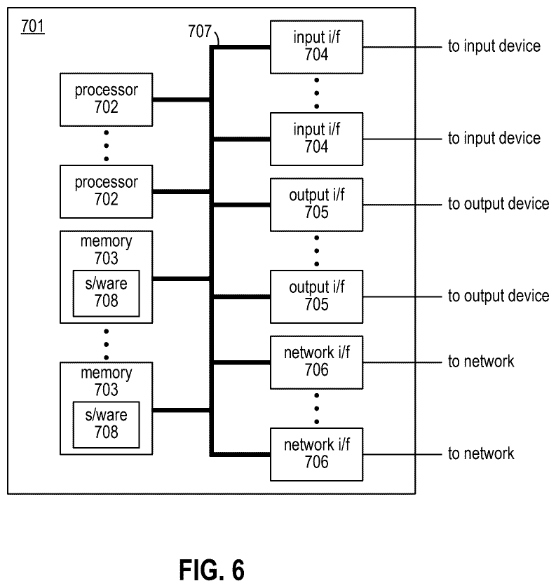

FIG. 6 is a block diagram of an example computing device 701, one or more of which may be used to implement the computing system 30, any of the computing devices 35 through 38, and/or other computing device(s) and to perform operations such as those described herein. Computing device 701 may comprise one or more processors 702, one or more memories 703, one or more input interface controllers 704, one or more output interface controllers 705, and one or more network interfaces 706, all of which may communicate over one or more busses 707. Processor(s) 702 may include any of various types of computational devices such as, without limitation, programmable microprocessors. Processor(s) 702 may execute instructions that cause computing device 701 to perform one or more operations such as are described herein. Memory(ies) 703 may include any of various types of non-transitory machine-readable storage media such as, without limitation, random access memory (RAM), read-only memory (ROM), FLASH memory, magnetic tape or discs, optical discs, etc. Memory(ies) 703 may be volatile or non-volatile. Input interface controller(s) 704 may include hardware and/or software that allow user input devices (e.g., a keyboard, a mouse, a touch screen) to communicate data to processor(s) 702. Output interface controller(s) 705 may include hardware and/or software that allow user output devices (e.g., display screens, printers) to output user understandable information based on data from processor(s) 702. Network interface(s) 706 may include hardware and/or software that allow processor(s) 702 to communicate with processors of other computers via one or more types of wired or wireless networks. Examples of network interfaces include, without limitation, Ethernet adaptors and Wi-Fi adaptors (e.g., operating in accordance with one or more IEEE 802.11 WLAN standards).

Memory(ies) 703 may store software 708 that provides instructions to processor(s) 702 that, when executed by processor(s) 702, cause computer 701 to perform some or all operations such as are described herein. Software 708 may comprise machine-executable instructions and/or other data, and may include both application software and operating system software. Executable instructions that cause computer 701 to perform operations such as are described herein may also or alternatively be stored in other forms, e.g., as firmware or as hardware logic in an integrated circuit.

Using the techniques described above, the present disclosure allows for the machine learning models to process (e.g., parse) information contained in a plurality of files to generate a file containing parts, components, elements, features, instructions, etc. associated with an engineering project. The file may then be inputted into a PLM tool that manages all of the information and processes at every step of a product or service lifecycle across globalized supply chains. By using the machine learning techniques described herein, a computer's ability to recognize individual parts, components, elements, features, instructions, etc. that form an engineering project is improved, thereby reducing the time it takes to ingest a new technical data package.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

1. A method comprising:
generating, by a computing device executing a product lifecycle management tool, a data package item, wherein the data package item comprises one or more of a name of the data package item, a description of the data package item, an owner of the data package item, a date the data package item was received, or a time the data package item was received;
receiving, by the computing device, a compressed data package associated with the data package item, wherein the compressed data package comprises a plurality of files indicating one or more parts, components, elements, features, or instructions associated with an engineering design;
decompressing, by the computing device, the compressed data package item to extract the plurality of files;
analyzing, using natural language processing, text of a first file, of the plurality of files, to identify one or more parts, components, elements, features, or instructions contained in the first file;
analyzing, using one or more machine learning models, the first file to extract one or more parts, components, elements, features, or instructions contained in one or more tables of the first file;
analyzing, using the one or more machine learning models, one or more images of the first file to identify one or more parts, components, elements, features, or instructions contained in the first file;
analyzing, using the one or more machine learning models, metadata of the first file to identify one or more parts, components, elements, features, or instructions contained in the first file;
aggregating each of the identified one or more parts, components, elements, features, or instructions identified in each of the plurality of files into a single file;
generating, based on the one or more parts, components, elements, features, or instructions contained in the single file, a bill of materials; and
causing, by the computing device, the bill of materials to be displayed on a user device.

2. The method of claim 1, wherein the compressed data package comprises at least one of:
an archive file; or
a technical data package.

3. The method of claim 1, further comprising:
training the one or more machine learning models to identify one or more parts, components, elements, features, or instructions, wherein training data used to train the one or more machine learning models comprises a plurality of technical data packages, each with a bill of materials associated therewith.

4. The method of claim 1, further comprising:
correlating, prior to aggregating each of the identify one or more parts, components, elements, features, or instructions identified in each of the plurality of files into the single file, each of the one or more parts, components, elements, features, or instructions identified during the text analysis with the one or more parts, components, elements, features, or instructions identified during the image analysis; and
based on a determination that one or more of the one or more parts, components, elements, features, or instructions identified during the text analysis does not correlate with the one or more parts, components, elements, features, or instructions identified during the image analysis, identifying one or more missing parts, components, elements, features, or instructions.

5. The method of claim 4, further comprising:
sending, to the user device, an electronic communication indicating the one or more missing parts, components, elements, features, or instructions.

6. The method of claim 1, wherein the aggregating each of the identified one or more parts, components, elements, features, or instructions identified in each of the plurality of files into the single file further comprising:
determining whether any of the identified one or more parts, components, elements, features, or instructions are duplicated.

7. The method of claim 6, further comprising:
based on a determination that at least one of the identified one or more parts, components, elements, features, or instructions are duplicated, sending, to the user device, an electronic communication indicating the one or more duplicated parts, components, elements, features, or instructions.

8. The method of claim 6, further comprising:
based on a determination that at least one of the identified one or more parts, components, elements, features, or instructions are duplicated, removing the one or more duplicated parts, components, elements, features, or instructions from the single file.

9. The method of claim 1, further comprising:
compiling, based on identifying a plurality of instructions in each of the plurality of files, a list of instructions for assembling one or more parts, components, elements, or features.

10. A computing device comprising:
one or more processors; and
memory storing instructions that, when executed by the one or more processors, cause the computing device to:
generate, using a product lifecycle management tool, a data package item, wherein the data package item comprises one or more of a name of the data package item, a description of the data package item, an owner of the data package item, a date the data package item was received, or a time the data package item was received;
receive a compressed data package associated with the data package item, wherein the compressed data package comprises a plurality of files indicating one or more parts, components, elements, features, or instructions associated with an engineering design;
decompress the compressed data package item to extract the plurality of files;
analyze, using natural language processing, text of a first file, of the plurality of files, to identify one or more parts, components, elements, features, or instructions contained in the first file;
analyze, using one or more machine learning models, the first file to extract one or more parts, components, elements, features, or instructions contained in one or more tables of the first file;
analyze, using the one or more machine learning models, one or more images of the first file to identify one or more parts, components, elements, features, or instructions contained in the first file;
analyze, using the one or more machine learning models, metadata of the first file to identify one or more parts, components, elements, features, or instructions contained in the first file;
aggregate each of the identified one or more parts, components, elements, features, or instructions identified in each of the plurality of files into a single file;
generate, based on the one or more parts, components, elements, features, or instructions contained in the single file, a bill of materials; and
cause the bill of materials to be displayed on a user device.

11. The computing device of claim 10, wherein the compressed data package comprises at least one of:
an archive file; or
a technical data package.

12. The computing device of claim 10, wherein the instructions, when executed by the one or more processors, cause the computing device to:
train the one or more machine learning models to identify one or more parts, components, elements, features, or instructions.

13. The computing device of claim 10, wherein the instructions, when executed by the one or more processors, cause the computing device to:
correlate, prior to aggregating each of the identify one or more parts, components, elements, features, or instructions identified in each of the plurality of files into the single file, each of the one or more parts, components, elements, features, or instructions identified during the text analysis with the one or more parts, components, elements, features, or instructions identified during the image analysis;
based on a determination that one or more of the one or more parts, components, elements, features, or instructions identified during the text analysis does not correlate with the one or more parts, components, elements, features, or instructions identified during the image analysis, identify one or more missing parts, components, elements, features, or instructions; and
send, to the user device, an electronic communication indicating the one or more missing parts, components, elements, features, or instructions.

14. The computing device of claim 10, wherein the instructions, when executed by the one or more processors, cause the computing device to aggregate each of the identified one or more parts, components, elements, features, or instructions identified in each of the plurality of files into the single file by determining whether any of the identified one or more parts, components, elements, features, or instructions are duplicated.

15. The computing device of claim 10, wherein the instructions, when executed by the one or more processors, cause the computing device to:
compile, based on identifying a plurality of instructions in each of the plurality of files, a list of instructions for assembling one or more parts, components, elements, or features.

16. A non-transitory computer-readable medium storing instructions that, when executed by one or more processors, configure a computing device to:
generate, using a product lifecycle management tool, a data package item, wherein the data package item comprises one or more of a name of the data package item, a description of the data package item, an owner of the data package item, a date the data package item was received, or a time the data package item was received;
receive a compressed data package associated with the data package item, wherein the compressed data package comprises a plurality of files indicating one or more parts, components, elements, features, or instructions associated with an engineering design;
decompress the compressed data package item to extract the plurality of files;
analyze, using natural language processing, text of a first file, of the plurality of files, to identify one or more parts, components, elements, features, or instructions contained in the first file;
analyze, using one or more machine learning models, the first file to extract one or more parts, components, elements, features, or instructions contained in one or more tables of the first file;
analyze, using the one or more machine learning models, one or more images of the first file to identify one or more parts, components, elements, features, or instructions contained in the first file;
analyze, using the one or more machine learning models, metadata of the first file to identify one or more parts, components, elements, features, or instructions contained in the first file;
aggregate each of the identified one or more parts, components, elements, features, or instructions identified in each of the plurality of files into a single file;
generate, based on the one or more parts, components, elements, features, or instructions contained in the single file, a bill of materials; and
cause the bill of materials to be displayed on a user device.

17. The non-transitory computer-readable medium of claim 16, wherein the instructions, when executed by the one or more processors, configure the computing device to:
train the one or more machine learning models to identify one or more parts, components, elements, features, or instructions.

18. The non-transitory computer-readable medium of claim 16, wherein the instructions, when executed by the one or more processors, configure the computing device to:
correlate, prior to aggregating each of the identify one or more parts, components, elements, features, or instructions identified in each of the plurality of files into the single file, each of the one or more parts, components, elements, features, or instructions identified during the text analysis with the one or more parts, components, elements, features, or instructions identified during the image analysis;
based on a determination that one or more of the one or more parts, components, elements, features, or instructions identified during the text analysis does not correlate with the one or more parts, components, elements, features, or instructions identified during the image analysis, identify one or more missing parts, components, elements, features, or instructions; and
send, to the user device, an electronic communication indicating the one or more missing parts, components, elements, features, or instructions.

19. The non-transitory computer-readable medium of claim 16, wherein the instructions, when executed by the one or more processors, configure the computing device to aggregate each of the identified one or more parts, components, elements, features, or instructions identified in each of the plurality of files into the single file by determining whether any of the identified one or more parts, components, elements, features, or instructions are duplicated.

20. The non-transitory computer-readable medium of claim 16, wherein the instructions, when executed by the one or more processors, configure the computing device to:
compile, based on identifying a plurality of instructions in each of the plurality of files, a list of instructions for assembling one or more parts, components, elements, or features.
